(19) United States
(12) Patent Application Publication
(10) Pub. No.: US 2015/0136202 A1
(43) Pub. Date: May 21, 2015

(54) HYBRID SOLAR GENERATOR

(71) Applicant: WITS ENGINEERING S.R.L., Pagani (IT)

(72) Inventors: Antonio Tiano, Pagani (IT); Luca Tiano, Pagani (IT); Aksana Bukshtynava, Pagani (IT)

(73) Assignee: WITS ENGINEERING S.R.L., Pagani (IT)

(21) Appl. No.: 14/396,376

(22) PCT Filed: Apr. 24, 2013
(86) PCT No.: PCT/IT2013/000121

§ 371 Date: Oct. 22, 2014

(30) Foreign Application Priority Data
Apr. 26, 2012 (IT) IT2012NA0001

(51) Int. Cl. H01L 31/052; H02S 40/42; H02S 40/44; H01L 31/048; H01L 31/042

(52) U.S. Cl. CPC H01L 31/0525; H01L 31/0521; H01L 31/0481; H01L 31/048; H02S 20/00; H02S 20/32; H02S 40/44; H02S 40/425
USPC 136/248

(57) ABSTRACT

A hybrid solar generator is described, comprising at least one photo-voltaic module contained inside at least one containing means which is at least partially transparent, such module being immersed at least partially into at least one dielectric fluid contained inside such containing means.

The present invention refers to an hybrid solar generator for producing electric and thermal energy.

Photo-voltaic modules are known in the art, composed of photo-voltaic cells, assembled in hybrid solar panels, typically used as generators of electric and thermal energy in a photo-voltaic plant.

Known photo-voltaic modules and related hybrid solar panels are equipped with an indirect cooling system to reduce the temperature of the photo-voltaic modules, increased by the radiating solar energy. Cooling of such known elements is usually provided by a thermal solar manifold placed on the rear surface of an hybrid solar panel, that operates as heat exchanger, characterised by an aluminium plate shaped as a serpentine circuit, in which a dielectric fluid circulates, which contributes to lower the operating temperature of the photo-voltaic panel; moreover, to avoid possible over-pressure phenomena due to the lack of capability of compressing the circulating fluid, the serpentine circuit ducts have different diameters at the entry and exit thereof. The known heat exchanger is adherent to the rear surface of the hybrid solar panel, implying a thermal dilatation of the exchanger which is greater than the maximum thermal dilatation of the solar panel or vice versa, generating a potential mechanical failure of one of the two components: an example of such system is disclosed, in particular, in WO2008/143482A2.

Currently, hybrid solar panels used as generators of current electric energy do not guarantee a continuous delivery of electric energy, being the operation of the photo-voltaic cells and consequently of the photo-voltaic modules subjected to the presence of sun-light.

Hybrid solar panels inserted in more complex photo-voltaic systems are also known, but they are constrained to the shape of the surface on which they are installed, consequently limiting the installation direction of the solar panels.

Anti-theft protection systems are also known for photo-voltaic modules, inserted in the related photo-voltaic plant, but not integrated in the single photo-voltaic module; they further have big sizes, whose installation requires specialised personnel: an example of such system is disclosed, in particular, in WO2011/151672A1.

Finally, known photo-voltaic modules have on their surface a protecting layer made of Ethylen Vinyl Acetate (EVA): such surface protecting system implies an increase of manufacturing costs for the modules and a difficult procedure for disposing of and recovering used materials.

Therefore, object of the present invention is solving the above prior art problems, by providing an hybrid solar generator which maximises the generation of electric and thermal energy.

A further object of the present invention is providing an hybrid solar generator adapted to use every type of existing photo-voltaic modules, in particular equipped with a protecting layer made of Ethylen Vinyl Acetate (EVA).

The above and other objects and advantages of the present invention, as will appear from the following description, are obtained with an hybrid solar generator like the one disclosed in the independent claim. Preferred embodiments and non-trivial variations of the present invention are the subject matter of the dependent claims.

It is clear that all enclosed claims are an integral part of the present description.

The present invention will be better described by some preferred embodiments thereof, provided as a non-limiting example, with reference to the enclosed drawings, in which:

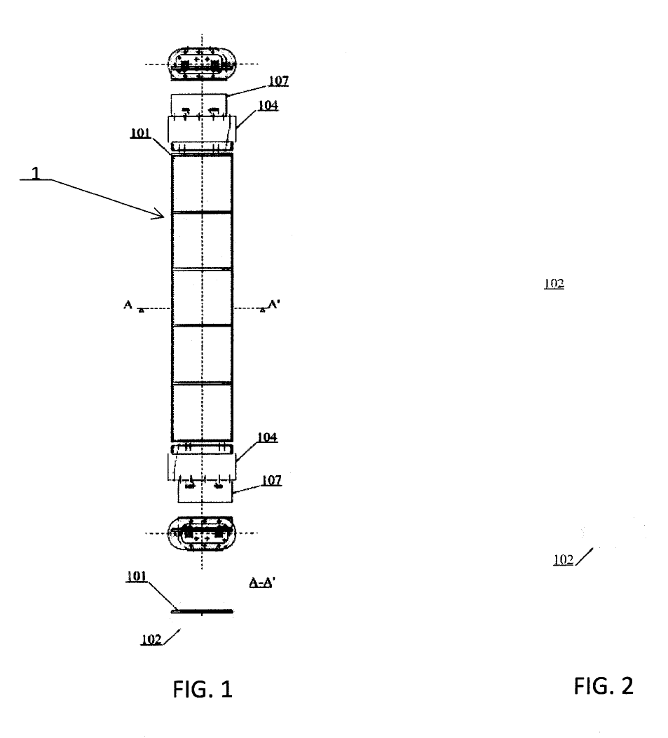

FIG. 1 is a side and sectional view of a preferred embodiment of the hybrid solar generator according to the present invention;

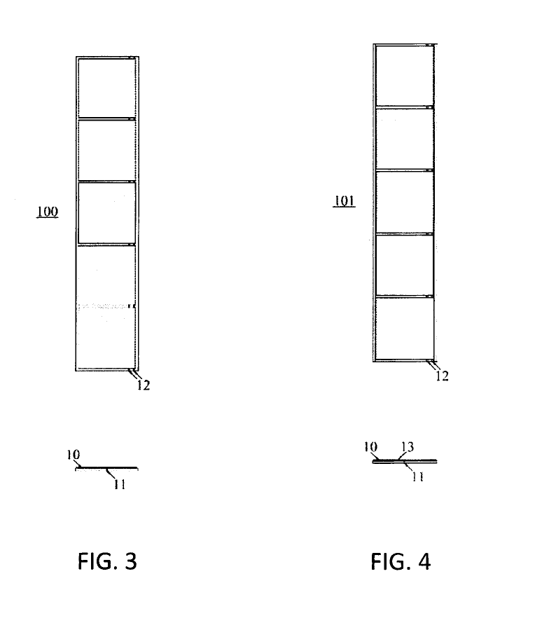

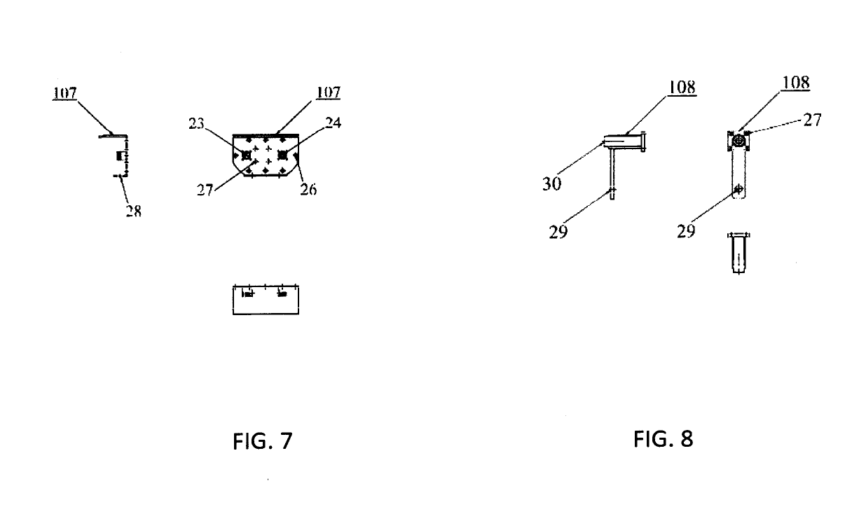

FIGS. 2, 3, 4, 6, 7, 8, 10 show side views of the main components of the hybrid solar generator according to the present invention;

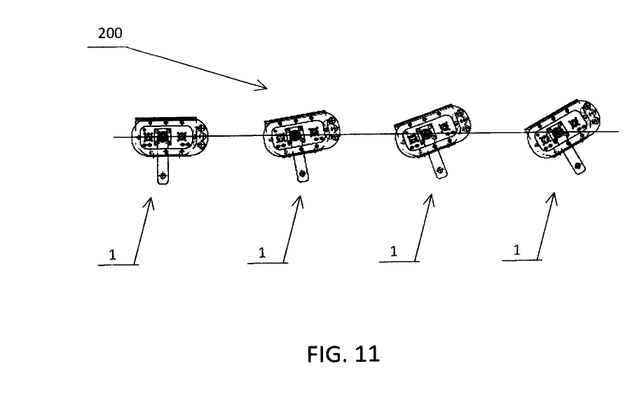

FIG. 11 shows a side view of a solar following system of the hybrid solar generator according to the present invention;

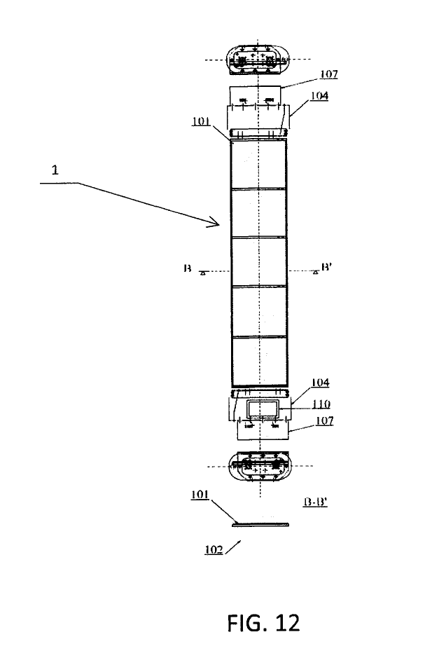

FIG. 12 shows a side and sectional view of a second preferred embodiment of the hybrid solar generator according to the present invention;

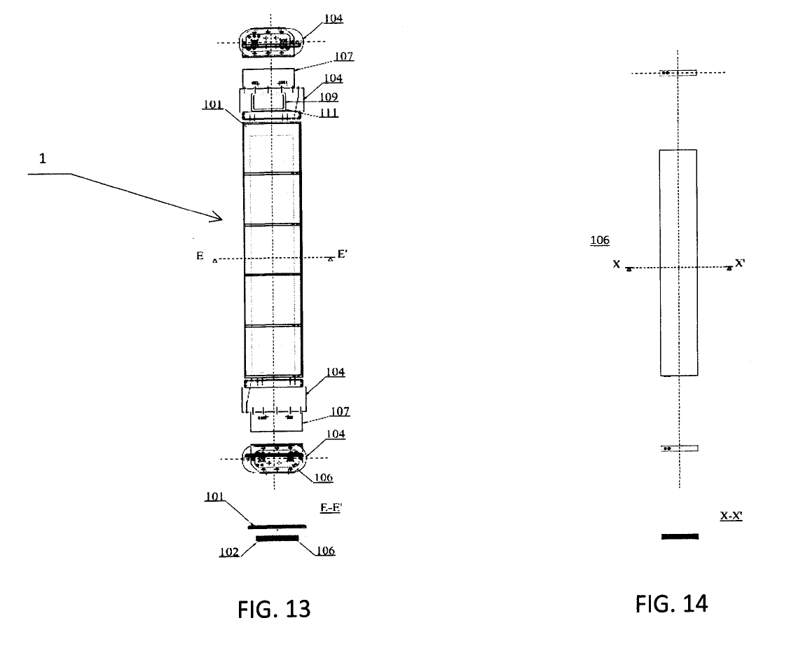

FIG. 13 shows a side and sectional view of a third preferred embodiment of the hybrid solar generator according to the present invention;

FIG. 14 shows a side view of a component of the third preferred embodiment of the hybrid solar generator according to the present invention;

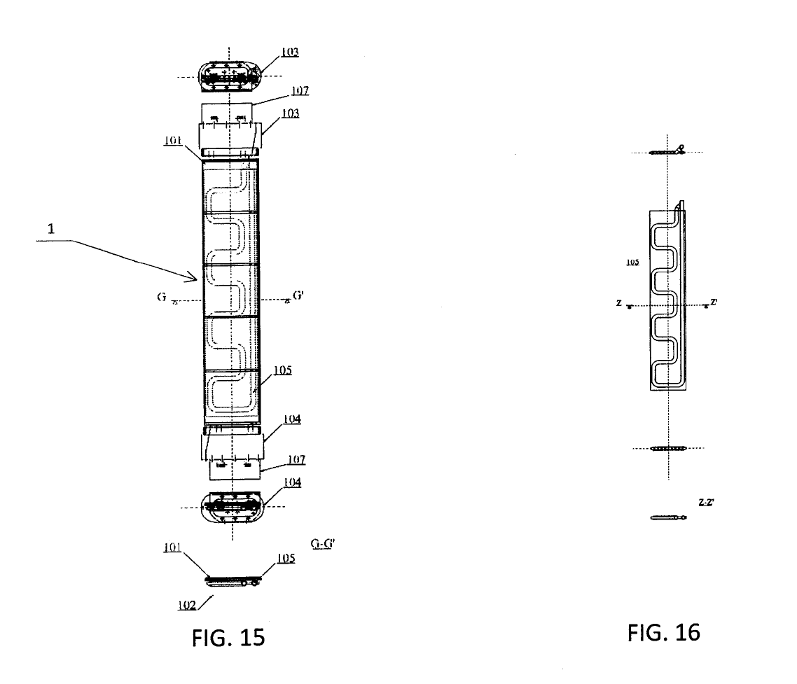

FIG. 15 shows a side and sectional view of a fourth preferred embodiment of the hybrid solar generator according to the present invention;

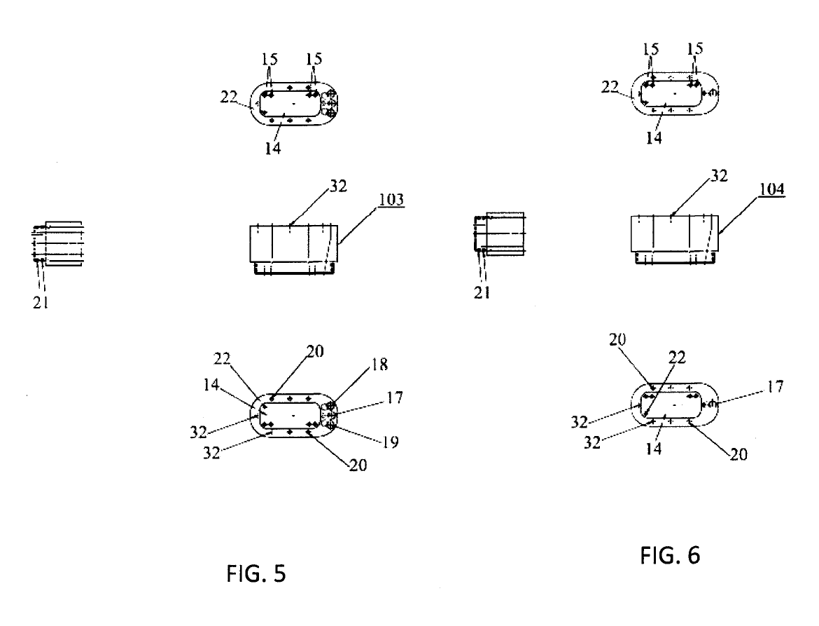

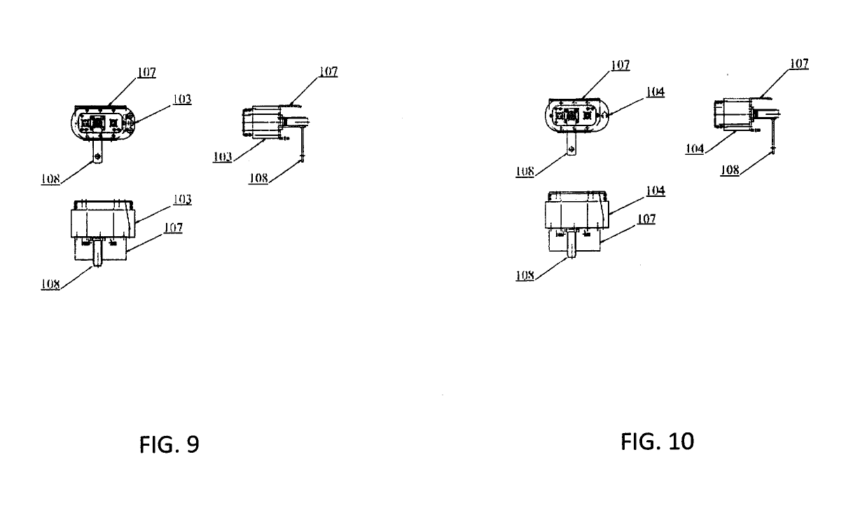

FIGS. 5, 9, 16 show side views of the components of a fourth preferred embodiment of the hybrid solar generator according to the present invention;

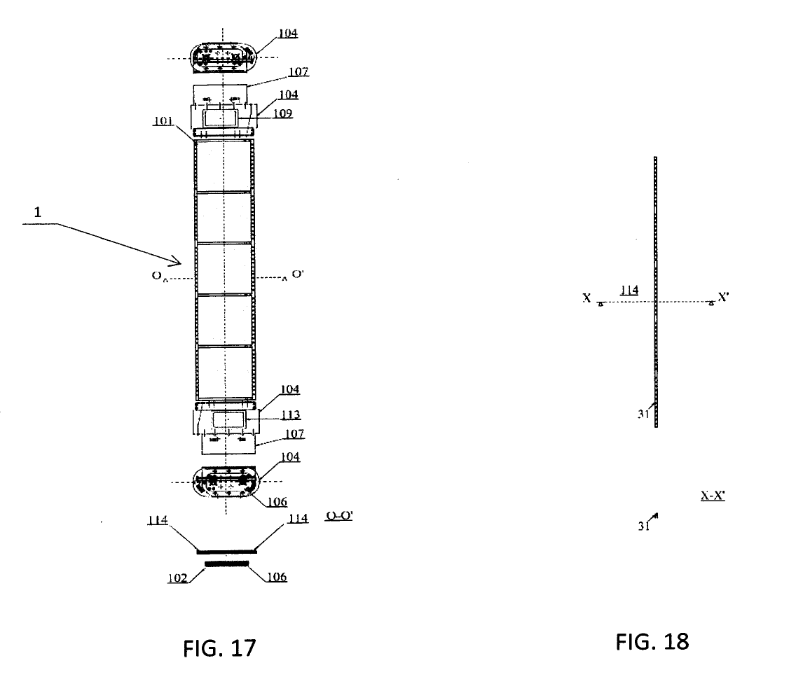

FIG. 17 shows a side and sectional view of a fifth preferred embodiment of the hybrid solar generator according to the present invention;

FIG. 18 shows a side view of a component of the fifth preferred embodiment of the hybrid solar generator according to the present invention;

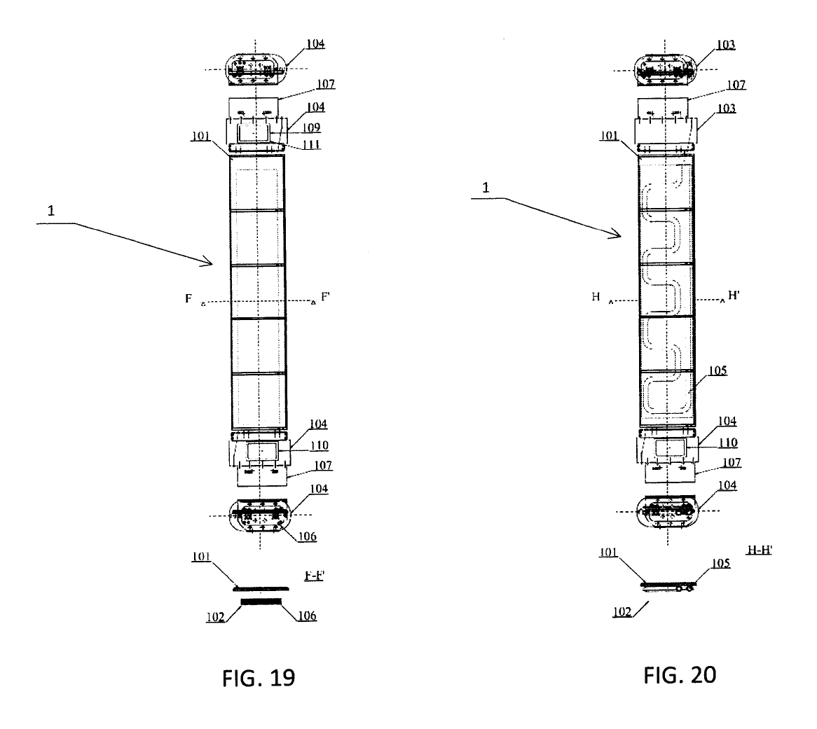

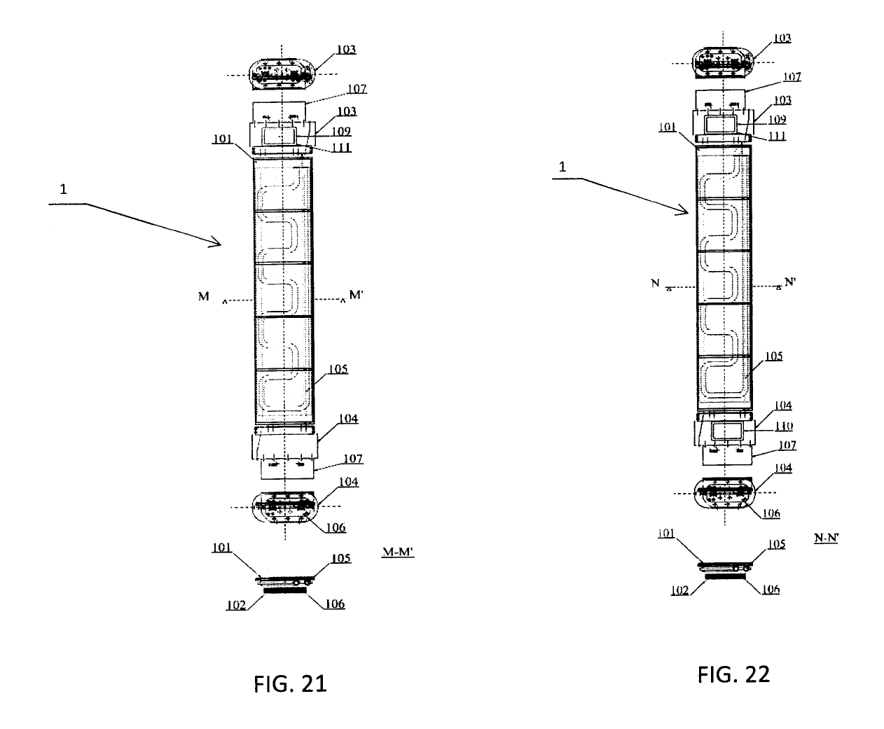

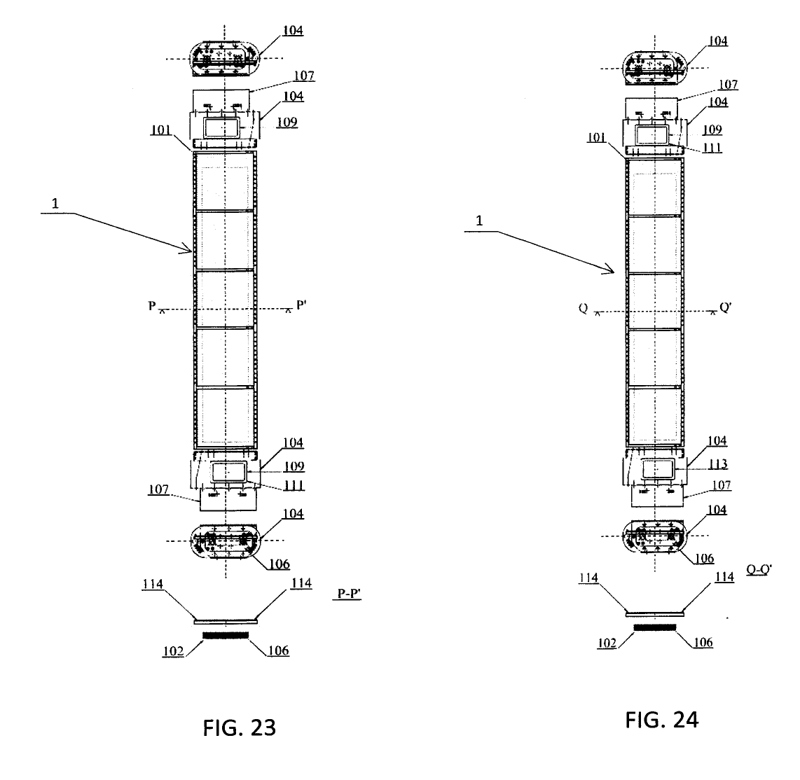

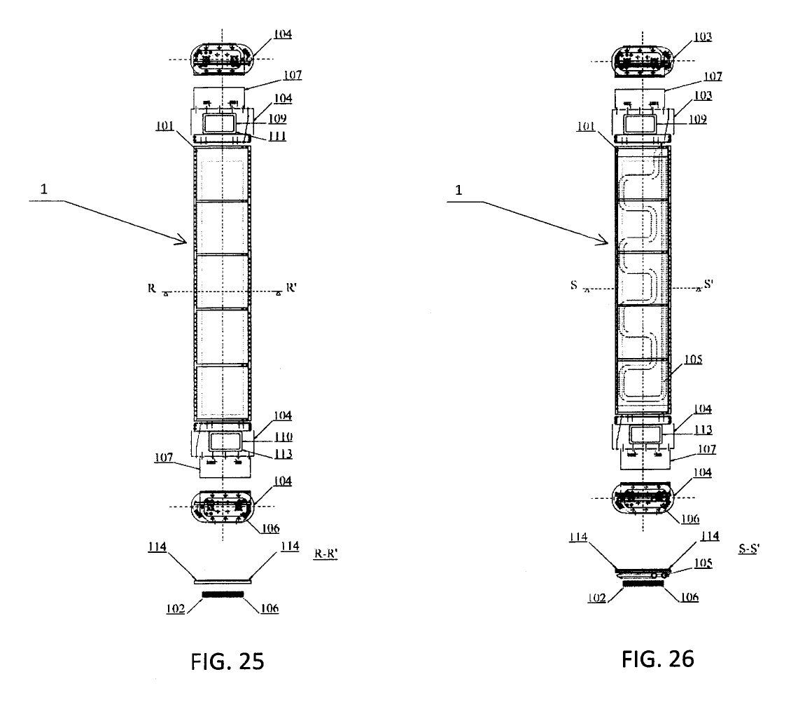

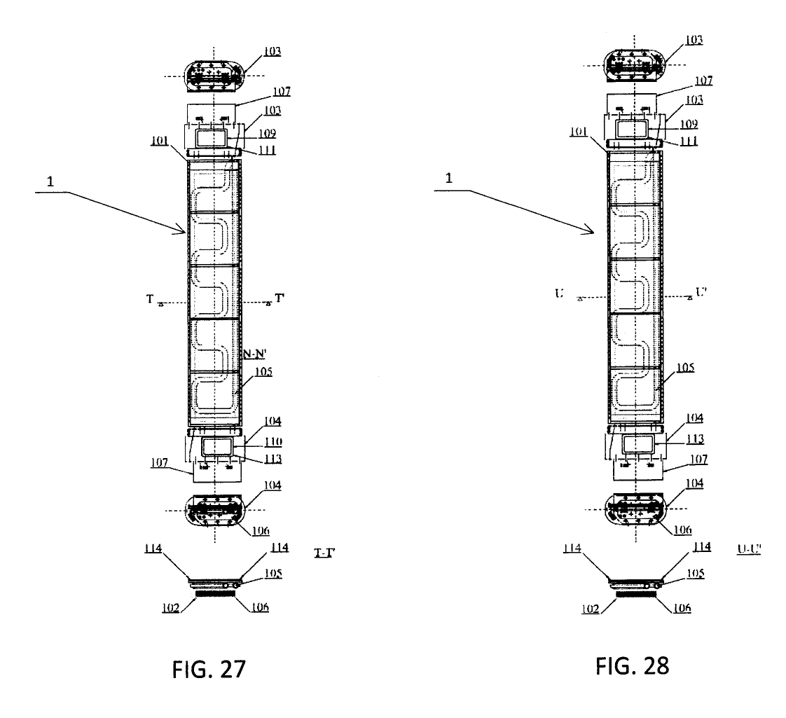

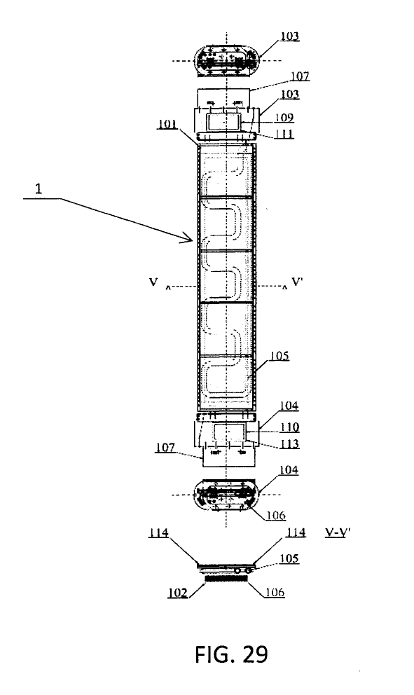

FIGS. 19 to 29 show side and sectional views of ten different preferred embodiments of the hybrid solar generator according to the present invention.

With reference to the Figures, a preferred embodiment of the present invention is shown and described. It will be immediately obvious that numerous variations and modifications (for example related to shape, sizes, arrangements and parts with equivalent functionality) could be made to what is described, without departing from the scope of the invention, as appears from the enclosed claims.

With reference to the Figures, the hybrid solar generator 1 according to the present invention comprises at least one photo-voltaic module 100 without any protecting layer, for example made of Ethylen Vinyl Acetate (EVA), and/or at least one photo-voltaic module 101 covered by at least one protecting surface layer 13, such layer 13 being preferably made of Ethylen Vinyl Acetate (EVA); both such modules 100 and 101 can be composed of photo-voltaic cells 10 made of amorphous crystalline, poly-crystalline silicon or other suitable material, arranged on the upper supporting surface 11 of the modules 100, 101 and mutually connected through suitably wired electric terminals 12.

The photo-voltaic module 100 and/or 101 is inserted inside at least one containing means 102, such containing means 102 being preferably of a cylindrical shape and such photo-voltaic module 100 and/or 101 being arranged along the internal median line of such cylindrical containing means 102, this latter one obviously having suitable section, length, thickness and curvature, such containing means 102 being made at least partially with at least one transparent or plastic material or other suitable material to allow the passage of sun radiations towards such photo-voltaic module 100 and/or 101: advantageously, at least such photo-voltaic module 100 and/or 101 is immersed at least partially into at least one dielectric fluid, such as a refrigerating dielectric fluid in liquid or gaseous form, or a mixture of dielectric refrigerating fluids in liquid or gaseous form, or other suitable medium contained inside such containing means 102.

The containing means 102 comprise two closing means 104, such as plugs, an upper one and a lower one, or other suitable means, and at least two covering and fastening means 107, such as covers or other suitable means for making an airtight sealing of the containing means 102.

The closing means 104 comprise:
at least one room 14 suitable to house at least one electronic control card, and possibly other electric components such as cables, connectors or other ones suitable for the electric wiring;
one or more holes 15 suitable for the passage of electric connections between such transparent containing means 102 and at least one electronic board;
at least one hole 17 suitable for the passage of such dielectric fluid inside such transparent containing means 102;
at least two sealing gaskets 21;
at least one duct 20, such as preferably a hole, a microphone or a micro-channel, suitable for the injection of sealing resins inside such closing means 104 next to such sealing gaskets 21; electric wirings, electronic boards and connectors are installed in the room 14 of the closing means 104 and 103. Once having completed the installation of the above components, the sealing and filling resin is poured inside the room 14, in the interspaces between the room 14 walls and the electronic boards, to protect the circuits from humidity and water, and to insulate the interior of the transparent pipe 102 from outside, since the sealing and filling resin also closes the holes 15. The dielectric fluid cannot go out of the room 14, but only of the hole 17. The above process for annealing the electronic circuits with resins is also defined as heating of electronic boards with resins or paints. As regards the improvement of airtightness globally, the two sealing gaskets 21, even if made of a suitable material, could yield or collapse after a certain time: to improve their performance through the duct 20, sealing and filling resin is injected next to the two sealing gaskets 21, and in this case it is not heating, but only resin coating;
at least one hole 22 for placing at least one thermal probe inside such transparent containing means 102;
at least one threaded hole 32 adapted to fasten such covering and fastening means 107 onto such closing means 104, such duct 20 being preferably obtained inside at least one of such threaded holes 32.

The covering and fastening means 107 are advantageously suitable also for the fastening of the hybrid solar generator 1 according to the present invention to a supporting structure, and for such purpose they comprise:
a lever-type system 108, associated with such covering and fastening means 107 through at least one fastening hole 27;
at least one direct current (DC) electric connector 23 connected to an electric terminal 12 of such photo-voltaic module 100 and/or 101, allowing to withdraw the electric energy produced by such module 100 and/or 101;
at least one alternate current (AC) electric connector 24;
at least one fastening hole 26 adapted to fasten such covering and fastening means 107 to such closing means 104 through at least one of such threaded hales 32;
at least one fastening hole 28 suitable to guarantee at least one fixed positioning of such hybrid solar generator 1 according to the present invention.

The lever-type system 108, comprising at least one fulcrum 30 and at least one hole 29, allows rotating the hybrid solar generator 1 according to the present invention along its own axis, enabling the solar following 200 of the hybrid solar generator 1 according to the present invention, guaranteeing operating conditions with maximum efficiency for the photo-voltaic module 100 and/or 101.

The thermal probe placed inside the containing means 102 is suitable to detect a temperature value of the dielectric fluid present inside the containing means 102, and to send a signal through the connector 23 placed on the covering and fastening means 107 to at least one remote controller. This latter one, when the signal received from the thermal probe exceeds the preset activation temperature value, generates a direct cooling of the module 100 and/or 101, inducing therein a forced circulation of the dielectric fluid inside the containing means 102. Moreover, the remote controller can activate the direct cooling also without the signal coming from the thermal probe, comparing at least one value of the external temperature of the environment in which the hybrid solar generator 1 according to the present invention is placed, measured by at least one external thermal probe and at least one electric power value generated by the photo-voltaic module 100 and/or 101.

The hybrid solar generator 1, as shown in FIG. 12, has a second preferred embodiment, comprising:
a different wiring of the electric terminals 12 of the photo-voltaic module 100 and/or 101;
at least one GPS locating device 110, supplied by activating the production process of electric energy, suitable to protect the module 100 and/or 101 against a possible theft, comparing the geographic coordinates of the detected position with those previously loaded in the locating device, such GPS locating device 110 being equipped with at least one power circuit suitable to enable and/or disable the supply of electric energy, produced by such photo-voltaic module 100 and/or 101, following the result obtained by comparing the coordinates.

The hybrid solar generator 1, as shown in FIG. 13, 14, has a third preferred embodiment, comprising:
a different wiring of the electric terminals 12 of the photo-voltaic module 100 and/or 101;
at least one electrolytic capacitor or accumulator 106 placed between the internal surface of the containing means 102 and the lower supporting surface 11 of the photo-voltaic module 100 and/or 101, suitable to accumulate the electric energy generated by the module 100 and/or 101 and to make it available to be used without a primary solar source; the dielectric fluid circulates inside the electrolytic capacitor or accumulator 106, and performs an insulating function between the plates of the electrolytic capacitor or accumulator 106;
at least one control circuit 109 (composed for example of a positive booster circuit) placed in the room 14 of the closing means 104 of the containing means 102, such control circuit 109 being suitable to boost the voltage of the electric energy generated by the module 100 and/or 101 and to send it to the electrolytic capacitor or accumulator 106;
at least one micro-inverter 111 placed in the closing means 104 of the transparent containing means 102 and connected to the connector 24 of the covering and fastening means 107, such micro-inverter 111 being adapted to withdraw the electric energy accumulated as direct current in the electrolytic capacitor or accumulator 106 and to transform it into alternate current.

Moreover, the hybrid solar generator 1, as shown in FIGS. 5, 9, 15 and 16, has a fourth preferred embodiment, comprising at least one heat exchanger 105 placed between the internal lower surface of the containing means 102 and the lower surface of the module 100 and/or 101, at least one upper closing means 103 distinguished from the upper closing means 104 due to the presence of at least two holes 18 and 19 adapted to pass at least one cooling fluid (dielectric or not, such as, for example, a mixture of water and antifreezing liquid) inside the heat exchanger 105. The closing means 103 comprise at least one thermal probe suitable to detect a temperature value of the dielectric fluid present inside the containing means 102, and to send a signal through the connector 23 placed on the covering and fastening means 107 to a remote controller.

Such remote controller, when the signal received from the thermal probe exceeds the preset activation temperature value, generates both an indirect cooling of the module 100 and/or 101 inducing in the heat exchanger 105 a forced circulation of the cooling fluid, and the direct cooling of such module 100 and/or 101, inducing therein a forced circulation of the dielectric fluid inside the containing means 102.

Moreover, such remote controller can activate the direct cooling also without the signal coming from the thermal probe, comparing at least one value of the external temperature of the environment in which the hybrid solar generator 1 according to the present invention is placed, detected by an external thermal probe and at least one electric power value generated by the photo-voltaic module 100 and/or 101.

Moreover, the hybrid solar generator 1, as shown in FIGS. 17 and 18, has a fifth preferred embodiment, comprising a different wiring of the electric terminals 12 and a system for signalling a position and transmitting data of the photo-voltaic module 100 and/or 101; the signalling system in particular comprises:
at least one diode bar 114 with liminous emission placed inside the containing means 102 along the side surface of the module 100 and/or 101, electrically supplied by the electric energy taken from the electrolytic capacitor or accumulator 106;
at least one electronic control module 113 inserted into the closing means 104 and connected to the connector 24 to allow managing the module 100 and/or 101 also from a possible external control unit.

Finally, the hybrid solar generator 1, as shown in FIGS. 19 to 29, has further preferred embodiments obtained from the various possible combinations of two or more of the features of the previously described preferred embodiments.

The hybrid solar generator 1 according to the present invention, therefore, has the following advantages:
allowing to use, inside the hybrid solar generator, any existing photo-voltaic module, equipped or not with a possible protecting surface layer made of Ethylen Vinyl Acetate (EVA);
integrating two different cooling systems of the photo-voltaic module, inserted inside the hybrid solar generator, maximising its efficiency and guaranteeing its use under extreme environmental conditions with very high external temperatures;
ensuring the operation of the hybrid solar generator during a possible contact or immersion thereof into liquid substances, guaranteeing its airtightness;
guaranteeing a protection of the hybrid solar generator against thefts through a GPS locating device with annexed power module, which enables or disables the electric energy supply of the photo-voltaic module;
guaranteeing the operation of the hybrid solar generator also without a primary solar source, through its integration with an electrolytic accumulator;
delivering alternate current electric energy, since the hybrid solar generator comprises an inverter integrated therein;
guaranteeing operating conditions with maximum efficiency for the photo-voltaic module contained in the hybrid solar generator arranged for the solar following or other objects through a rotation along its own axis;
providing the hybrid solar generator with an active system for luminous position signalling and data transmission through luminoos pulses;
allowing to install the hybrid solar generator on different surfaces;
preventing the deterioration of the photo-voltaic module contained inside the hybrid solar generator, improving its working life;
reducing the production costs of the photo-voltaic modules, allowing the use in the hybrid solar generator of photo-voltaic modules which, lacking the EVA surface layer, can be re-used and re-cycled;
simplifying the manufacturing methodologies of an hybrid solar generator and reducing installation times and costs for the system;
reducing possible over-pressure problems inside the hybrid solar generator by using dielectric fluids capable of being compressed.

1-15. (canceled)

16. A hybrid solar generator comprising at least one photo-voltaic module contained inside at least one containing means that is at least partially transparent, where the at least one photo-voltaic module is at least partially immersed into at least one dielectric fluid contained inside the at least one containing means.

17. The hybrid solar generator of claim 16, where the dielectric fluid is a refrigerating dielectric fluid in liquid form, gaseous form, or both liquid and gaseous form.

18. The hybrid solar generator of claim 16, where the photo-voltaic module is covered by at least one protecting surface layer.

19. The hybrid solar generator of claim 18, where the layer is preferably made of Ethylene Vinyl Acetate.

20. The hybrid solar generator of claim 16, where the photo-voltaic module comprises photo-voltaic cells made of amorphous crystalline, polycristalline silicon or both amorphous crystalline and polycristalline silicon, arranged on an upper supporting surface of the at least one photo-voltaic module and mutually connected through electric terminals.

21. The hybrid solar generator of claim 16, where the containing means comprise a substantially cylindrical shape and the at least one photo-voltaic module is placed along a median line of the cylindrical containing means.

22. The hybrid solar generator of claim 16, where the containing means comprise at least two closing means and at least two covering and a fastening means adapted to form an airtight seal of the containing means, the at least two closing means comprising:
a) at least one room adapted to house at least one electronic control board and at least one or more other electric components suitable for at least one electric wiring;
b) one or more holes adapted to pass electric connections between the transparent containing means and the electronic board;
c) at least one hole adapted to pass the dielectric fluid inside the transparent containing means;
d) at least one duct adapted at least to allow an injection of at least one or more sealing resins inside the closing means;
e) at least two sealing gaskets;
f) at least one hole for placing at least one thermal probe inside the transparent containing means; and
g) at least one threaded hole adapted to fasten the covering and fastening means onto the closing means, the duct being preferably obtained inside at least one of the threaded holes.

23. The hybrid solar generator of claim 22, where the covering and fastening means is adapted to fasten the hybrid solar generator to at least one supporting structure and comprises:
a) at least one lever-type system, associated with the covering and fastening means through at least one fastening hole;
b) at least one direct current electric connector connected to at least one electric terminal of the photo-voltaic module;
c) at least one alternate current electric connector;
d) at least one fastening hole adapted to fasten the covering and fastening means to the closing means through at least one of the threaded holes; and
e) at least one fastening hole adapted to guarantee at least one fixed positioning of the hybrid solar generator.

24. The hybrid solar generator of claim 23, where the lever-type system comprises at least one fulcrum and at least one hole, the lever-type system being adapted to allow a rotation of the hybrid solar generator along its own axis, favouring a solar following of the hybrid solar generator.

25. The hybrid solar generator of claim 24, where the thermal probe is adapted to detect at least one temperature value of the dielectric fluid present inside the containing means, and to send at least one signal through the connector to at least one remote controller adapted to perform a direct cooling of the module inducing a forced circulation of the dielectric fluid inside the transparent containing means, when the temperature value exceeds at least one activation temperature value.

26. The hybrid solar generator of claim 25, further comprising at least one GPS locating device equipped with at least one power circuit adapted to enable and disable a delivery activity of electric energy of the photo-voltaic module.

27. The hybrid solar generator of claim 26 further comprising:
a) at least one electrolytic capacitor placed between an internal surface of the containing means and a lower supporting surface of the module, where the at least one electrolytic capacitor or accumulator being adapted to accumulate the electric energy generated by the photo-voltaic module and to make it available to be used without a primary solar source;
b) at least one control circuit placed in the room in the closing means of the transparent containing means, the control circuit being adapted to boost at least one voltage value of the electric energy generated by the module and to send it to the electrolytic capacitor; and
c) at least one micro-inverter placed in the closing means of the containing means and connected to the connector of the covering and fastening means, the micro-inverter being adapted to take electric energy accumulated as direct current in the electrolytic capacitor and to transform it into alternate current.

28. The hybrid solar generator of claim 26 further comprising:
a) at least one electrolytic accumulator placed between an internal surface of the containing means and a lower supporting surface of the module, where the at least one electrolytic accumulator being adapted to accumulate the electric energy generated by the photo-voltaic module and to make it available to be used without a primary solar source;
b) at least one control circuit placed in the room in the closing means of the transparent containing means, the control circuit being adapted to boost at least one voltage value of the electric energy generated by the module and to send it to the electrolytic accumulator; and
c) at least one micro-inverter placed in the closing means of the containing means and connected to the connector of the covering and fastening means, the micro-inverter being adapted to take electric energy accumulated as direct current in the electrolytic accumulator and to transform it into alternate current.

29. The hybrid solar generator of claim 26 further comprising:
a) at least one heat exchanger placed between an internal lower surface of the containing means and a lower surface of the module; and
b) at least one upper closing means comprising at least two opening adapted to pass at least one cooling fluid inside the heat exchanger.

30. The hybrid solar generator of claim 26, where the remote controller is further adapted to perform an indirect cooling of the module inducing a forced circulation of the cooling fluid in the heat exchanger.

31. The hybrid solar generator of 26, where the remote controller is adapted to activate the direct cooling also without the signal coming from the thermal probe, by comparing at least one external temperature value of an environment in which the hybrid solar generator is placed through an external thermal probe and at least one electric power value generated by the photovoltaic module.

32. The hybrid solar generator of claim 26 further comprising at least one system for position signaling and data transmission of the photovoltaic module, the signaling system comprising:
a) at least one diode bar with luminous emission placed inside the containing means, transparent along a side surface of the module and electrically supplied by electric energy taken from the electrolytic capacitor or accumulator; and
b) at least one electronic control module inserted into the closing means and connected to the connector, the electronic control module being adapted to allow managing the module through at least one external control unit.
